(19) United States
(12) Patent Application Publication
(10) Pub. No.: US 2025/0151599 A1
(43) Pub. Date: May 8, 2025

(54) LIGHT-EMITTING ELEMENT, METHOD FOR MANUFACTURING DISPLAY PANEL, AND DISPLAY PANEL

(71) Applicant: HKC CORPORATION LIMITED, Shenzhen (CN)

(72) Inventors: YAO LI, Shenzhen (CN); Lidan YE, Shenzhen (CN)

(21) Appl. No.: 18/938,330

(22) Filed: Nov. 6, 2024

(30) Foreign Application Priority Data
Nov. 7, 2023 (CN) 202311470185.8

(51) Int. Cl. H10K 71/16; H10K 50/115; H10K 59/35

(52) U.S. Cl. CPC H10K 71/166; H10K 50/115; H10K 59/353

(57) ABSTRACT

A manufacturing method includes: forming multiple hollow nanospheres of different sizes, the multiple hollow nanospheres being respectively filled with red light-emitting particles, blue light-emitting particles, and green light-emitting particles; performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate; heating all the hollow nanospheres so as to sublimate; and forming a red light-emitting particle layer, a green light-emitting particle layer, and a blue light-emitting particle layer on the substrate. The hollow nanospheres of different sizes are filled with light-emitting particles of different colors.

### CROSS-REFERENCE TO RELATED APPLICATIONS

This application claims the priority and benefit of Chinese patent application number 2023114701858, titled “Light-emitting Element, Method for Manufacturing Display Panel, and Display Panel” and filed Nov. 7, 2023 with China National Intellectual Property Administration, the entire contents of which are incorporated herein by reference.

### TECHNICAL FIELD

This application relates to the field of display technology, and more particularly relates to a light-emitting element, a method for manufacturing a display panel, and a display panel.

### BACKGROUND

The description provided in this section is intended for the mere purpose of providing background information related to the present application but doesn't necessarily constitute prior art.

Organic light emitting diodes (OLEDs) have the advantages of surface light source, cold light, energy saving, fast response, flexibility, ultra-thinness, and low cost. Furthermore, their mass production technology is becoming increasingly mature. The light-emitting element of OLED may be composed of thin films of three luminous colors, RGB, and a patterning process is required in the process of producing the light-emitting thin films of the three colors. As a non-contact patterning technology, inkjet printing can directly pattern ink droplets at designated locations on a substrate. Another method is forming a light-emitting element by mask evaporation.

However, the light-emitting element in the OLED device has many film layers, including at least a hole injection layer, a hole transport layer, a light-emitting layer, an electron transport layer, and electron injection layer. Whether the inkjet printing or mask evaporation is used, each film layer needs to be produced before the next film layer can be produced, resulting in low producing efficiency of the light-emitting elements and affecting the delivery speed of display panels. Therefore, how to improve the efficiency of the film-forming process of OLED light-emitting elements is crucial.

### SUMMARY

It is therefore one purpose of this application to provide a light-emitting element, a method for manufacturing a display panel, and a display panel to improve the efficiency of the-film forming process of the light-emitting element and improve the production efficiency of the display panel.

The present application discloses a method for manufacturing a light-emitting element, includes:
forming hollow nanospheres of various sizes, wherein the plurality of hollow nanospheres are respectively filled with red light-emitting particles, blue light-emitting particles and green light-emitting particles;
performing screening so that the hollow nanospheres filled with red light-emitting particles are located in the red sub-pixel area of the substrate, the hollow nanospheres filled with green light-emitting particles are located in the green sub-pixel area of the substrate, and the hollow nanospheres filled with blue light-emitting particles are located in the blue sub-pixel area of the substrate;
heating all hollow nanospheres, so that the hollow nanospheres sublimate, thus forming a red light-emitting particle layer, a green light-emitting particle layer, and a blue light-emitting particle layer on the substrate;
forming a red light-emitting element, a green light-emitting element, and a blue light-emitting element;
where hollow nanospheres of different sizes are filled with light-emitting particles of different colors.

In some embodiments, the hollow nanospheres are formed of an iodine material.

In some embodiments, the radial width of the hollow nanosphere is greater than or equal to 50 nm and less than or equal to 500 nm.

In some embodiments, the hollow nanospheres of various sizes include first nanosphere, second nanosphere, and third nanosphere with sequentially increasing radial widths. The radial width of the first nanosphere is 50 nm-100 nm. The radial width of the second nanosphere is 100 nm-150 nm. The radial width of the third nanosphere is 150 nm-200 nm. The first nanosphere is filled with red light-emitting particles. The second nanosphere is filled with green light-emitting particles. The third nanosphere is filled with blue light-emitting particles.

In some embodiments, the step of performing screening so that the hollow nanosphere filled with red light-emitting particles is located in the red sub-pixel area of the substrate, the hollow nanosphere filled with green light-emitting particles is located in the green sub-pixel area of the substrate, and the hollow nanosphere filled with blue light-emitting particles is located in the blue sub-pixel area of the substrate includes:
forming a bottom electrode on the substrate;
forming an isolation layer on the bottom electrode, forming a plurality of pixel openings in the isolation layer, and exposing the bottom electrode from the pixel openings, where the pixel openings include a red sub-pixel area, a green sub-pixel area, and a blue sub-pixel area;
wherein in the step of performing screening so that the hollow nanosphere filled with red light-emitting particles is located in the red sub-pixel area of the substrate, the hollow nanosphere filled with green light-emitting particles is located in the green sub-pixel area of the substrate, and the hollow nanosphere filled with blue light-emitting particles is located in the blue sub-pixel area of the substrate, a composite molecular sieve structure is used to filter hollow nanospheres of various sizes in sequence;
and wherein the step of forming the red light-emitting element, the green light-emitting element, and the blue light-emitting element includes forming a top electrode to form the red light-emitting element, the green light-emitting element, and the blue light-emitting element.

In some embodiments, the step of performing screening so that the hollow nanosphere filled with red light-emitting particles is located in the red sub-pixel area of the substrate, the hollow nanosphere filled with green light-emitting particles is located in the green sub-pixel area of the substrate, and the hollow nanosphere filled with blue light-emitting particles is located in the blue sub-pixel area of the substrate includes:
using a first molecular sieve membrane to filter out the hollow nanospheres filled with red light-emitting particles, and depositing them in the red sub-pixel area;
using a second molecular sieve membrane to filter out the hollow nanospheres filled with green light-emitting particles, and depositing them in the green sub-pixel area;
using a third molecular sieve membrane to filter out the hollow nanosphere filled with blue light-emitting particles, and depositing them in the blue sub-pixel area;

The composite molecular sieve structure includes a first molecular sieve membrane, a second molecular sieve membrane, and a third molecular sieve membrane. The composite molecular sieve structure includes a first molecular sieve membrane corresponding to the red sub-pixel area. The composite molecular sieve structure includes a second molecular sieve membrane corresponding to the blue sub-pixel. The composite molecular sieve structure includes a third molecular sieve membrane corresponding to the green sub-pixel.

In some embodiments, the composite molecular sieve structure further includes a first cover plate, a second cover plate, and a third cover plate. The first cover plate is disposed corresponding to the first molecular sieve membrane. The second cover plate is disposed corresponding to the second molecular sieve membrane. The third cover plate is disposed corresponding to the third molecular sieve membrane.

The step of performing screening so that the hollow nanosphere filled with red light-emitting particles is located in the red sub-pixel area of the substrate, the hollow nanosphere filled with green light-emitting particles is located in the green sub-pixel area of the substrate, and the hollow nanosphere filled with blue light-emitting particles is located in the blue sub-pixel area of the substrate includes:
opening the first cover plate and closing the second cover plate and the third cover plate, filtering out the hollow nanosphere filled with red light-emitting particles through the first molecular sieve membrane, and depositing it in the red sub-pixel area;
opening the second cover plate and closing the first cover plate and the third cover plate, filtering out the hollow nanosphere filled with green light-emitting particles through the second molecular sieve membrane, and depositing it in the green sub-pixel area;
opening the third cover plate and closing the first cover plate and the second cover plate, filtering out the hollow nanosphere filled with blue light-emitting particles through the third molecular sieve membrane, and depositing it in the blue sub-pixel area.

In some embodiments, the step of heating all the hollow nanospheres thus sublimating the hollow nanospheres, and forming a red light-emitting particle layer, a green light-emitting particle layer, and a blue light-emitting particle layer on the substrate includes:
heating the substrate to a preset temperature;
the hollow nanospheres closer to the substrate sublimating first, and the hollow nanospheres in the direction away from the substrate gradually sublimating;
forming the red light-emitting layer, the green light-emitting layer, and the blue light-emitting layer.

The present application discloses a method for manufacturing a display panel, comprising:
making a light-emitting element using the above-mentioned method for manufacturing a light-emitting element;
forming an encapsulation layer;
forming a display panel.

The present application further discloses a display panel, including a light-emitting element formed by the above-mentioned method for manufacturing a light-emitting element.

In the present application, the light-emitting particles of various colors in the light-emitting element are respectively filled into hollow nanospheres of different sizes. In the operation of forming light-emitting elements of different colors, the light-emitting particles of different colors can be screened out by screening the sizes and deposited into the corresponding light-emitting elements respectively. Thus, it is possible to form red light-emitting particles in the red light-emitting element, green light-emitting particles in the green light-emitting element, and blue light-emitting particles in the blue light-emitting element. After the light-emitting particles of different colors are screened out, light-emitting elements of various colors can be formed through a single manufacturing process. Compared with the technical solution of forming the various film layers in the light-emitting element layer by layer through inkjet printing in the exemplary technology, the present application forms the light-emitting layers in the light-emitting elements of multiple colors through a one-step process, which simplifies the process and saves the time of the light-emitting element process, thereby improving the efficiency of light-emitting element production and the production efficiency of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a flowchart of a method for making a light-emitting element according to the present application.

FIG. 2 is a schematic diagram illustrating a heating and sublimation process of a hollow nanosphere according to the present application.

FIG. 3 is a schematic diagram illustrating hollow nanospheres of various sizes according to the present application.

FIG. 4 is a schematic diagram of a composite molecular sieve structure according to the present application.

FIG. 5 is a schematic diagram illustrating a method for making a light-emitting element according to the present application.

FIG. 6 is a schematic diagram of a light-emitting element according to another embodiment of the present application.

FIG. 7 is a schematic diagram of another multilayer molecular sieve structure according to the present application.

FIG. 8 is a flowchart of a method for making a display panel according to the present application.

In the drawings: 100, light-emitting element; 100a, membrane layer particle; 101, hole injection layer; 102, hole transport layer; R, red light-emitting particle; G, green light-emitting particle; B, blue light-emitting particle; 110, bottom electrode; 112, isolation column; 200, hollow nanosphere; 201, first nanosphere; 202, second nanosphere; 203, third nanosphere; 204, fourth nanosphere; 205, fifth nanosphere; 300, composite molecular sieve structure; 301, first molecular sieve membrane; 302, second molecular sieve membrane; 303, third molecular sieve membrane; 304, first cover plate; 305, second cover plate; 306, third cover plate; 310, multilayer molecular sieve structure; 311, fourth molecular sieve membrane; 312, fifth molecular sieve membrane.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

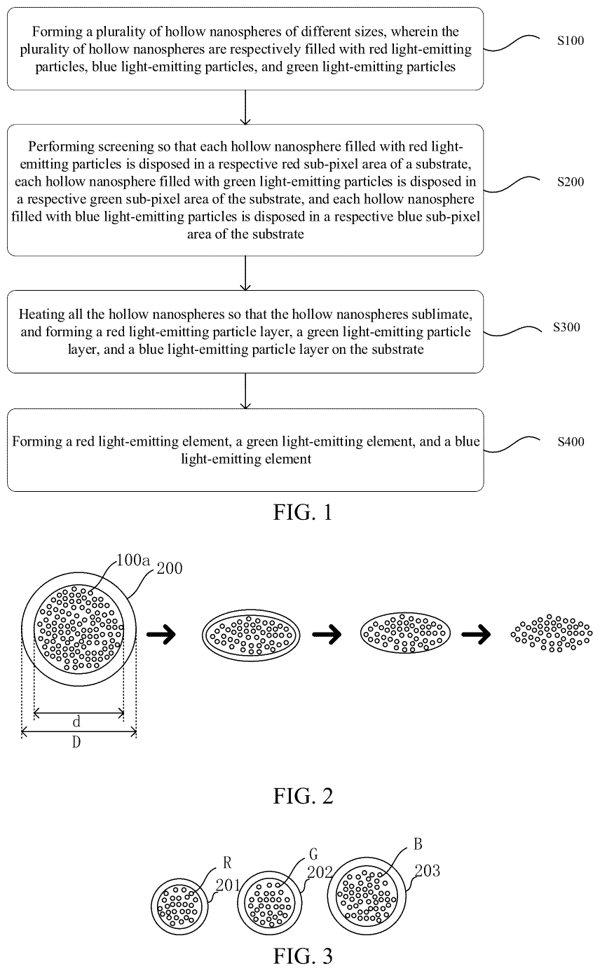

FIG. 1 is a flowchart of a method for making a light-emitting element according to the present application. As shown in FIG. 1, the present application discloses a method for making a light-emitting element, including the following operations:
S100: forming hollow nanospheres of various sizes, wherein the plurality of hollow nanospheres are respectively filled with red light-emitting particles, blue light-emitting particles, and green light-emitting particles;
S200: performing screening so that the hollow nanosphere filled with red light-emitting particles is located in the red sub-pixel area of the substrate, the hollow nanosphere filled with green light-emitting particles is located in the green sub-pixel area of the substrate, and the hollow nanosphere filled with blue light-emitting particles is located in the blue sub-pixel area of the substrate;
S300: heating all hollow nanospheres so that the hollow nanospheres sublime, thus forming a red light-emitting particle layer, a green light-emitting particle layer, and a blue light-emitting particle layer on the substrate;
S400: forming a red light-emitting element, a green light-emitting element, and a blue light-emitting element; wherein hollow nanospheres of different sizes are filled with light-emitting particles of different colors.

In the present application, the light-emitting particles of various colors in the light-emitting element are respectively filled into hollow nanospheres of different sizes. In the operation of forming light-emitting elements of different colors, the light-emitting particles of different colors can be screened out by screening the sizes and deposited into the corresponding light-emitting elements respectively. Thus, it is possible to form red light-emitting particles in the red light-emitting element, green light-emitting particles in the green light-emitting element, and blue light-emitting particles in the blue light-emitting element. After the light-emitting particles of different colors are screened out, light-emitting elements of various colors can be formed through a single manufacturing process. Compared with the technical solution of forming the various film layers in the light-emitting element layer by layer through inkjet printing in the exemplary technology, the present application forms the light-emitting layers in the light-emitting elements of multiple colors through a one-step process, which simplifies the process and saves the time of the light-emitting element process, thereby improving the efficiency of light-emitting element production and the production efficiency of the display panel.

As a non-contact patterning technology, inkjet printing can directly pattern ink droplets at designated locations on a substrate. Inkjet printing first melts the light-emitting element material in a solvent to make it into an ink shape. The ink containing the light-emitting element material is sprayed onto the substrate through a nozzle of an inkjet head, and printed between the gratings of the substrate. Finally, after the solvent is removed through the drying process, the printing of OLED materials is completed. Due to the technical characteristics of inkjet printing, each functional layer needs to be sprayed separately, and has to be dried before the next layer can be produced. It can be understood that, taking the OLED display panel with RGB as the light sources as an example, the light-emitting elements include a red light-emitting element, a green light-emitting element, and a blue light-emitting element. The materials of the respective light-emitting layer in the three colors are different. In the exemplary technology, the red light-emitting element, the green light-emitting element, and the blue light-emitting element needs to be formed separately in separate steps. For example, after forming a red light-emitting element, a blue light-emitting element or a green light-emitting element is formed. Furthermore, when forming the next film layer, the inkjet device needs to be replaced, which is extremely time-consuming. For the Tandem OLED technology route with multiple layers of light-emitting materials, the producing efficiency is extremely low, and the spraying precision in inkjet printing is also required to be extremely high.

It can be understood that in this application, only the red light-emitting element, the green light-emitting element, and the blue light-emitting element are used as examples for explanation. However, in the OLED display panel, there can be light-emitting elements of multiple colors, such as white light-emitting element and yellow light-emitting element.

In this application, the membrane layer particles formed by the light-emitting layer materials of the light-emitting elements of different colors, that is, the light-emitting particles, are wrapped in nanospheres of different particle sizes. Using the screening structure, hollow nanospheres of different particle sizes are filtered and deposited, so that the light-emitting particles of different colors fall into different pixel opening areas (including red sub-pixel area, green sub-pixel area and blue sub-pixel area). After the light-emitting layers of all light-emitting elements are completed, heating is performed to directly sublimate the nanospheres, and the membrane layer particles wrapped inside will be released and uniformly formed into films, which can significantly increase the film formation rate of the organic light-emitting layers.

In S100, the production of the hollow nanosphere can use an ultrasonic chemical method, a hydrothermal method or a template method. In this step, the production of the hollow nanospheres and light-emitting element materials can be completed in the material factory before they are directly transported to the panel factory, or directly produced in the panel factory. This application separates the production of hollow nanosphere from the process of display panel, and the two can be carried out simultaneously, further reducing the process time of the display panel.

Specifically, the hollow nanosphere is formed by an iodine material. Iodine can start to sublimate at a temperature of about 45 degrees and can be completely sublimated at about 77 degrees. In this embodiment, iodine material is selected as the material of hollow nanosphere. In the subsequent processes, the hollow nanosphere can be completely removed by heating to an appropriate temperature, leaving only the membrane layer particle to form a membrane layer. The process in which a solid substance evaporates directly into steam without going through a liquid process is called “sublimation”. Sublimation is an endothermic process. Sublimation may occur on the surface of any solid at room temperature and pressure. Iodine is a solid substance at room temperature and sublimates under slight heat. Iodine has low chemical activity and may not react with metals. It is worth mentioning that the hollow nanosphere of the present application includes but is not limited to iodine materials, and other materials with the same sublimation characteristics are also applicable to the present application.

FIG. 2 is a schematic diagram illustrating a heating sublimation process of a hollow nanosphere according to the present application. As shown in FIG. 2, the hollow nanosphere 200 is spherical before heating. After gradual heating, the hollow nanosphere gradually ellipsoidizes until the hollow nanosphere is completely sublimated. The membrane layer particles 100a of the light-emitting element material inside the hollow nanosphere is dispersed from the hollow nanosphere to form a light-emitting element material layer. During the sublimation process, the spherical shape will deform as the spherical material sublimates. The thickness of the sphere gradually decreases, and the shape gradually becomes elliptical or flat. During the shape change process, the membrane layer particles 100a contained in the sphere will also be redistributed along with the change of the spherical shape, and finally a flattening effect may be presented. After the sphere sublimates, the membrane layer particles will remain to form a film.

Specifically, a radial width D of the hollow nanosphere is greater than or equal to 50 nm and less than or equal to 500 nm. The radial width D of the hollow nanosphere in the present application refers to the particle size of the hollow nanosphere, and in this embodiment, different light-emitting element materials are distinguished mainly by judging the radial widths D of the hollow nanospheres. The thickness of each film layer in the light-emitting element may be in the micron level. Correspondingly, in a film layer, a large number of hollow nanospheres are required for filling, and before the hollow nanospheres are sublimated, the formed films have a certain degree of flatness. Even after the hollow nanospheres are sublimated, the interface between the film layers can be guaranteed. The hollow width of the hollow nanosphere 200 is d, which refers to the width of the inner cavity of the hollow nanosphere, where the radial width of the hollow nanosphere is equal to the sum of the hollow width and twice the thickness.

Specifically, the difference in radial widths of the hollow nanospheres corresponding to light-emitting particles of different colors is less than or equal to 100 nm and greater than or equal to 10 nm. In this embodiment, the size difference of the hollow nanospheres corresponding to the light-emitting particles of different colors cannot be too small. If it is too small, the precision will be insufficient when using the screening structure, resulting in the problem of mixing of light-emitting particles of different colors. On the contrary, the difference in radial widths of the hollow nanospheres corresponding to the light-emitting particles of different colors cannot be too large. If it is too large, the hollow nanospheres of the same size cannot be completely filtered out when hollow nanospheres of different sizes pass through the screening structure.

FIG. 3 is a schematic diagram of hollow nanospheres of various sizes according to the present application. As shown in FIG. 3, the hollow nanospheres 200 of various sizes include a first nanosphere 201, a second nanosphere 202, and a third nanosphere 203, whose radial widths increase successively. The radial width of the first nanosphere 201 is 50 nm-100 nm. The radial width of the second nanosphere 202 is 100 nm-150 nm. The radial width of the third nanosphere 203 is 150 nm-200 nm. The first nanosphere 201 is filled with red light-emitting particles R. The second nanosphere 201 is filled with green light-emitting particles G. The third nanosphere 203 is filled with blue light-emitting particles B.

The shell thickness corresponding to hollow nanospheres of different sizes may be consistent or substantially the same.

Specifically, in the operation of S200, it includes:

S210: forming a bottom electrode on a substrate;

S211: forming an isolation layer on the bottom electrode, forming a plurality of pixel openings on the isolation layer, and exposing the bottom electrode from the pixel openings, wherein the pixel openings include a red sub-pixel area, a green sub-pixel area, and a blue sub-pixel area.

In the operation of S200, a multilayer molecular sieve structure is used to filter hollow nanospheres of various sizes in sequence.

In the operation of S500, it includes forming a top electrode to form a light-emitting element.

In this embodiment, a plurality of pixel openings are formed by patterning the isolation layer. The plurality of pixel openings are divided into a plurality of red sub-pixel areas, a plurality of green sub-pixel areas, and a plurality of blue sub-pixel areas. A pixel unit is formed by a red sub-pixel areas, a green sub-pixel area, and a blue sub-pixel area that are adjacent. In this solution, hollow nanospheres of various sizes are placed together. During the deposition process, first, the first nanospheres with the smallest size are filtered out using a multilayer molecular sieve structure, and the filtered out first nanospheres are deposited in the red sub-pixel area to form a red light-emitting element in the red sub-pixel area. Secondly, all the second nanospheres with the second largest size are filtered out and deposited in the green sub-pixel area to form a green light-emitting element in the green sub-pixel area. Finally, all the remaining third nanospheres are deposited in the blue sub-pixel area to form a blue light-emitting element in the blue sub-pixel area.

Specifically, in the operation S200, it further includes:
S201: using the first molecular sieve membrane to filter out the hollow nanospheres filled with red light-emitting particles, and depositing them in the red sub-pixel area; wherein the hollow nanosphere filled with red light-emitting particles is the first nanosphere.
S202: using a second molecular sieve membrane and filtering out hollow nanospheres filled with green light-emitting particles, and depositing them in the green sub-pixel area; wherein the hollow nanosphere filled with green light-emitting particles is the second nanosphere.
S203: using a third molecular sieve membrane to filter out the hollow nanospheres filled with blue light-emitting particles and depositing them in the blue sub-pixel area. The hollow nanosphere filled with blue light-emitting particles is the third nanosphere.

In this embodiment, all the first nanospheres, second nanospheres, and third nanospheres are separated in turn through the composite molecular sieve structure.

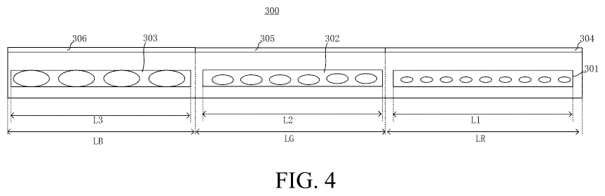

FIG. 4 is a schematic diagram of a composite molecular sieve structure according to the present application. As shown in FIG. 4, the composite molecular sieve structure 300 includes a first molecular sieve membrane 301, a second molecular sieve membrane 302, and a third molecular sieve membrane 303. The composite molecular sieve structure 300 includes a first molecular sieve membrane 301 corresponding to the red sub-pixel area. The composite molecular sieve structure 300 includes a second molecular sieve membrane 302 corresponding to the blue sub-pixel. The composite molecular sieve structure 300 includes a third molecular sieve membrane 303 corresponding to the green sub-pixel.

Specifically, the composite molecular sieve structure 300 further includes a first cover plate 304, a second cover plate 305, and a third cover plate 306. The first cover plate 304 is disposed corresponding to the first molecular sieve membrane 301. The second cover plate 305 is disposed corresponding to the second molecular sieve membrane 302. The third cover plate 306 is disposed corresponding to the third molecular sieve membrane 303.

Take the radial width of the first nanosphere 201 of 100 nm, the radial width of the second nanosphere 202 of 150 nm, and the radial width of the third nanosphere 203 of 200 nm as an example for explanation. The filtering size of the first molecular sieve membrane 301 is such that the first nanosphere 201 can pass through, while the second nanosphere 202 and the third nanosphere 203 cannot pass through. The filtering size of the second molecular sieve membrane 202 is such that the second nanosphere 202 can pass through, while the third nanosphere 203 cannot pass through. The filtering size of the third molecular sieve membrane 203 is such that the third nanosphere 203 can pass through.

The first cover plate 304, the second cover plate 305 and the third cover plate 306 etc. disposed in the present application can be selectively covered or removed. The first molecular sieve membrane 301, the second molecular sieve membrane 302, and the third molecular sieve membrane 303 are placed in a template structure. When the first cover plate is opened, the first molecular sieve membrane is exposed and can perform normal filtering functions. The second cover plate and the third cover plate are closed to prevent the first nanospheres from falling into the green sub-pixel area and the blue sub-pixel area.

It is worth mentioning that the positions of the three molecular sieves, namely the first molecular sieve membrane, the second molecular sieve membrane, and the third molecular sieve membrane in this embodiment can be adjusted and arranged at will on the entire template structure. For example, if the widths of the areas where the light-emitting layers in the light-emitting elements need to be deposited are LR/LG/LB respectively, then the widths of the corresponding molecular sieve areas L1/L2/L3 would be smaller than LR/LG/LB respectively, but the upper cover plate needs to be larger than LR/LG/LB. Although the width of the molecular sieve is smaller than the coating area, the nanospheres can be rolled and laid flat by vibration during actual filtration. Furthermore, when the sizes of L1/L2/L3 are fixed, different LR/LG/LB products can be applicable. In use, it is only needed to adjust the positions and spacings of the three molecular sieves to adapt to products with different PPIs, and it can be reused.

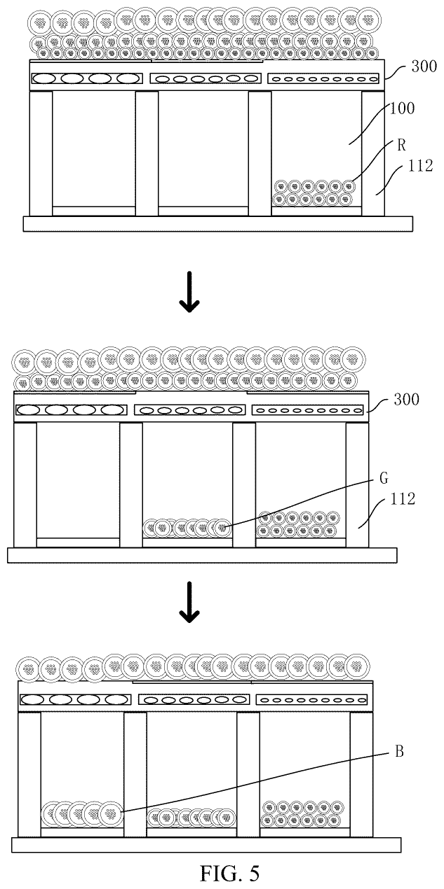

FIG. 5 is a schematic diagram illustrating a method for making a light-emitting element according to the present application. As shown in FIG. 5, when the light-emitting layer of the red sub-pixel area is coated, the second cover plate and the third cover plate are covered. At this time, all hollow nanospheres are laid on the entire surface, and only in the red sub-pixel area is formed a red light-emitting element.

In S201, the first cover plate is opened, while the second cover plate and the third cover plate are closed. The hollow nanospheres filled with red light-emitting particles are filtered out through the first molecular sieve membrane and deposited in the red sub-pixel area.

In S202, the second cover plate is opened, while the first cover plate and the third cover plate are closed. The hollow nanospheres filled with green light-emitting particles are filtered out through the second molecular sieve membrane and deposited in the green sub-pixel area.

In S203, the third cover plate is opened, while the first cover plate and the second cover plate are closed. The hollow nanospheres filled with blue light-emitting particles are filtered out through the third molecular sieve membrane and deposited in the blue sub-pixel area.

Specifically, S300 includes:
S301: heating the substrate to a preset temperature;
S302: the hollow nanospheres closer to the substrate sublimate first, and the hollow nanospheres in the direction facing away from the substrate gradually sublimate;
S303: forming a red light-emitting layer, a green light-emitting layer, and a blue light-emitting layer.

In this solution, a red light-emitting layer, a green light-emitting layer and a blue light-emitting layer are formed, and then an electron transport layer, an electron injection layer and a top electrode are formed to form a light-emitting element 100. By heating one side of the substrate, the hollow nanospheres sublimate from the position closest to the substrate and gradually rises. The sublimated hollow nanosphere gas moves upward. At this time, the upper film layer has not yet formed and is in a spherical state. The sublimated particles can be discharged through the gap between the spheres, which can increase the sublimation rate and avoid the pinholes in the film layer caused by sublimation. This can be done upward in sequence to improve the density of the film layer.

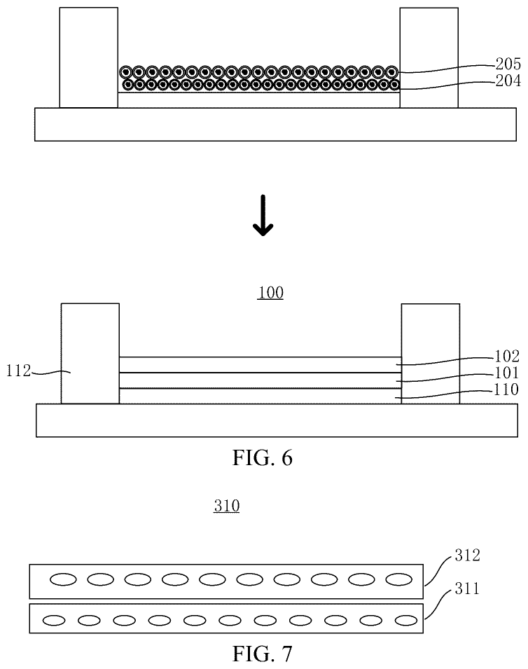

FIG. 6 is a schematic diagram of a light-emitting element according to another embodiment of the present application. As shown in FIG. 6, in another embodiment, the display principle of OLED (Organic Light Emitting Diode) is simply the phenomenon of luminescence caused by carrier injection and recombination under the drive of an electric field. The principle is using an ITO transparent electrode and a metal electrode as the top electrode and bottom electrode of the device respectively. Under the drive of a certain voltage, electrons and holes are respectively injected from the top electrode and bottom electrode through the electron injection layer (EIL) and the hole injection layer (HIL) into the electron transport layer (ETL) and the hole transport layer (HTL), and then migrate to the emission layer (EML), where they meet to form excitons to excite the luminescent molecules, which emit visible light after radiation.

This application takes the five-layer film structure in the above-mentioned light-emitting element as an example for explanation. It can be understood that in actual situations, the size of the hollow nanosphere that can be designed in this application can vary with the number of film layers.

The above steps are only intended to form light-emitting layers of multiple colors. For light-emitting elements of different colors, the only difference lies in slightly different materials of the light-emitting layer. However, for the hole injection layer, hole transport layer, electron transport layer, and electron injection layer, the materials required for the light-emitting elements of different colors are the same. The hole injection layer, hole transport layer, electron transport layer, and electron injection layer of the sub-pixel areas of different colors in this embodiment.

Take the hole transport layer and the hole injection layer as an example. The membrane layer particles of the hole transport layer are filled into the fourth nanosphere, and the membrane layer particles of the hole injection layer are filled into the fifth nanosphere. The radial width of the fourth nanosphere is different from the radial width of the fifth nanosphere, and the radial width of the fifth nanosphere is larger.

FIG. 7 is a schematic diagram of another multilayer molecular sieve structure according to the present application. As shown in FIG. 7, the present application further includes another molecular sieve structure, where the multilayer molecular sieve structure 310 includes two layers of molecular sieve membranes, and each layer of molecular sieve membrane corresponds to a different filtering size. The fourth molecular sieve membrane 311 and the fifth molecular sieve membrane 312 are included, and the filtration size of the fifth molecular sieve membrane 312 is larger than the filtration size of the fourth molecular sieve membrane 311. The fourth molecular sieve membrane 311 can allow the fourth nanosphere 204 to pass through but cannot allow the fifth nanosphere 205 to pass through. The fifth molecular sieve membrane 312 can allow the fifth nanosphere 205 to pass through. By stacking the fourth molecular sieve membrane 311 and the fifth molecular sieve membrane 312, the hole transport layer and the hole injection layer can be formed in one process.

Specifically, multiple layers of molecular sieve membranes with different filtration sizes are stacked to form a multilayer molecular sieve structure. A layer of the smallest hollow nanospheres is filtered out using the multilayer molecular sieve structure, so that a hole injection layer is formed on the bottom electrode. After removing the molecular sieve membrane with the smallest filtration size, the multilayer molecular sieve structure is used to continue filtering the smallest hollow nanosphere among the remaining hollow nanospheres of various sizes to form another hollow transport layer. After the light-emitting layers of different colors are completed, the above operations are repeated in sequence until hollow nanospheres of various sizes are stacked on the substrate according to their sizes to form an electron transport layer and an electron injection layer. The multilayer molecular sieve structure includes multiple layers of molecular sieve membranes with different filtration sizes, and the filtration sizes of the molecular sieve membranes are set in a one-to-one correspondence with the sizes of the hollow nanospheres.

It can be understood that the filtering step in the present application can complete the filtration of multiple hollow nanospheres of different sizes in one step. Then, multiple film layers are formed in a stacked arrangement, including but not limited to the hole injection layer, the hole transport layer, the electron transport layer, and the electron injection layer mentioned above.

In one embodiment, all hollow nanospheres can be placed in an inkjet printing box. A multilayer molecular sieve structure is disposed in a nozzle of the inkjet printer. After each film layer is formed, the corresponding first molecular sieve membrane is removed, and the process is repeated in sequence to complete the production of the multiple film layers in the light-emitting element. It is worth mentioning that the multilayer molecular sieve structure of the present application can be reused, and the hollow nanospheres can be provided by the material factory, which can greatly improve the production efficiency of the display panel.

Specifically, the substrate is heated to a preset temperature. The hollow nanospheres closer to the substrate sublimate first, and the hollow nanospheres in the direction facing away from the substrate gradually sublimate. As such, a multi-layer stacked light-emitting material layer is formed.

In this embodiment, the sublimation speed of the hollow nanospheres is related to the heating speed. The faster the heating, the faster the corresponding hollow nanosphere sublimates. In this solution, heating is performed on one side of the substrate. It takes a certain amount of time for heat to be transferred, that is, it takes a certain amount of time for the hole injection layer on the substrate to be transferred to the electron injection layer. Therefore, the heat will be transferred to the hole injection layer first, and after the hollow nanosphere of the hole injection layer breaks and sublimates, the heat will gradually be transferred to the hole transport layer. Furthermore, the hollow nanospheres of the hole injection layer absorb heat during sublimation and delay the time for the heat to reach the hole transport layer, so that after the hollow nanospheres of the hole injection layer are completely sublimated, the heat continues to enter the hollow transport layer. Through the above process, the hole injection layer, the hole transport layer, the light-emitting layer, electron transport layer, and the electron injection layer in the light-emitting element can be made, which can be completed without a high temperature, and the performance of the light-emitting element is not affected at all.

In another embodiment, in order to ensure the uniformity of the hollow nanospheres falling on the substrate after filtering from the molecular sieve structure, the substrate can be slightly shaken appropriately. The shaking direction is parallel to the bottom surface of the substrate to achieve better flatness of the film layer.

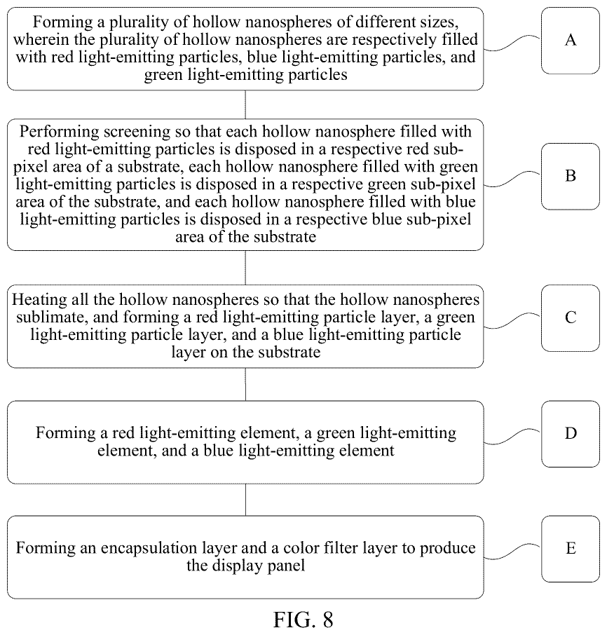

FIG. 8 is a flowchart of a method for making a display panel according to the present application. As shown in FIG. 8, the present application discloses a method for making a display panel, including:
A: forming hollow nanospheres of various sizes, where the plurality of hollow nanospheres are respectively filled with red light-emitting particles, blue light-emitting particles, and green light-emitting particles;
B: performing screening so that the hollow nanosphere filled with red light-emitting particles is located in the red sub-pixel area of the substrate, so that the hollow nanosphere filled with green light-emitting particles is located in the green sub-pixel area of the substrate, and so that the hollow nanosphere filled with blue light-emitting particles is located in the blue sub-pixel area of the substrate;
C: heating all hollow nanospheres so that the hollow nanospheres sublimate, thus forming a red light-emitting particle layer, a green light-emitting particle layer, and a blue light-emitting particle layer on the substrate;
D: forming a red light-emitting element, a green light-emitting element, and a blue light-emitting element;
E: forming an encapsulation layer and a color filter layer to form a display panel.

Correspondingly, the present application further discloses a display panel, including a light-emitting element formed by the above-mentioned method for making a light-emitting element. It can be understood that the display panel mentioned in the present application is an OLED display panel, and the corresponding light-emitting element is an organic light-emitting element.

In the present application, the light-emitting particles of various colors in the light-emitting element are respectively filled into hollow nanospheres of different sizes. In the operation of forming light-emitting elements of different colors, the light-emitting particles of different colors can be screened out by screening the sizes and deposited into the corresponding light-emitting elements respectively. Thus, it is possible to form red light-emitting particles in the red light-emitting element, green light-emitting particles in the green light-emitting element, and blue light-emitting particles in the blue light-emitting element. After the light-emitting particles of different colors are screened out, light-emitting elements of various colors can be formed through a single manufacturing process. Compared with the technical solution of forming the various film layers in the light-emitting element layer by layer through inkjet printing in the exemplary technology, the present application forms the light-emitting layers in the light-emitting elements of multiple colors through a one-step process, which simplifies the process and saves the time of the light-emitting element process, thereby improving the efficiency of light-emitting element production and the production efficiency of the display panel.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A method for manufacturing a light-emitting element, comprising:
forming a plurality of hollow nanospheres of different sizes, wherein the plurality of hollow nanospheres are respectively filled with red light-emitting particles, blue light-emitting particles, and green light-emitting particles;
performing screening so that each hollow nanosphere filled with red light-emitting particles is disposed in a respective red sub-pixel area of a substrate, each hollow nanosphere filled with green light-emitting particles is disposed in a respective green sub-pixel area of the substrate, and each hollow nanosphere filled with blue light-emitting particles is disposed in a respective blue sub-pixel area of the substrate;
heating all the hollow nanospheres so that the hollow nanospheres sublimate, and forming a red light-emitting particle layer, a green light-emitting particle layer, and a blue light-emitting particle layer on the substrate; and
forming a red light-emitting element, a green light-emitting element, and a blue light-emitting element;
wherein the plurality of hollow nanospheres of different sizes are filled with light-emitting particles of different colors respectively.

2. The method as recited in claim 1, wherein each of the plurality of hollow nanosphere is formed of an iodine material.

3. The method as recited in claim 1, wherein each of the plurality of hollow nanosphere has a radial width that is greater than or equal to 50 nm and less than or equal to 500 nm.

4. The method as recited in claim 1, wherein the plurality of hollow nanospheres of different sizes comprise a first nanosphere, a second nanosphere, and a third nanosphere with sequentially increasing radial widths; wherein the first nanosphere has a radial width that lies in the range of 50 nm-100 nm, wherein second nanosphere has a radial width that lies in the range of 100 nm-150 nm, wherein the third nanosphere has a radial width that lies in the range of 150 nm-200 nm; wherein the first nanosphere is filled with red light-emitting particles, wherein the second nanosphere is filled with green light-emitting particles, and wherein the third nanosphere is filled with blue light-emitting particles.

5. The method as recited in claim 1, further comprising the following operations prior to the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate:
forming a bottom electrode on the substrate; and
forming an isolation layer on the bottom electrode, defining a plurality of pixel openings in the isolation layer and exposing the bottom electrode from the pixel openings, wherein the plurality of pixel openings comprise the red sub-pixel area, the green sub-pixel area, and the blue sub-pixel area;
wherein in the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate, the plurality of hollow nanospheres of different sizes are screened in sequence using a composite molecular sieve structure;
wherein the operation of forming the red light-emitting element, the green light-emitting element, and the blue light-emitting element comprises forming a top electrode to form the red light-emitting element, the green light-emitting element, and the blue light-emitting element.

6. The method as recited in claim 5, wherein the composite molecular sieve structure comprises a first molecular sieve membrane disposed corresponding to the red sub-pixel areas, a second molecular sieve membrane disposed corresponding to the blue sub-pixel areas, and a third molecular sieve membrane disposed corresponding to the green sub-pixel areas;
wherein the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate comprises:
using the first molecular sieve membrane to screen out each hollow nanosphere filled with red light-emitting particles, and depositing the hollow nanosphere filled with red light-emitting particles in the respective red sub-pixel area;
using the second molecular sieve membrane to screen out each hollow nanosphere filled with green light-emitting particles, and depositing the hollow nanosphere filled with green light-emitting particles in the respective green sub-pixel area; and
using the third molecular sieve membrane to screen out each hollow nanosphere filled with blue light-emitting particles, and depositing the hollow nanosphere filled with blue light-emitting particles in the respective blue sub-pixel area.

7. The method as recited in claim 6, wherein the composite molecular sieve structure further comprises a first cover plate, a second cover plate and a third cover plate, wherein the first cover plate is arranged corresponding to the first molecular sieve membrane, wherein the second cover plate is arranged corresponding to the second molecular sieve membrane, and wherein the third cover plate is arranged corresponding to the third molecular sieve membrane; wherein the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate comprises:
opening the first cover plate and closing the second cover plate and the third cover plate, and screening out each hollow nanosphere filled with red light-emitting particles through the first molecular sieve membrane, and depositing each hollow nanosphere filled with red light-emitting particles in the respective red sub-pixel area;
opening the second cover plate and closing the first cover plate and the third cover plate, and screening out each hollow nanosphere filled with green light-emitting particles through the second molecular sieve membrane, and depositing each hollow nanosphere filled with green light-emitting particles in the respective red sub-pixel area;
opening the third cover plate and closing the first cover plate and the second cover plate, and screening out each hollow nanosphere filled with blue light-emitting particles through the third molecular sieve membrane, and depositing each hollow nanosphere filled with blue light-emitting particles in the respective blue sub-pixel area.

8. The method as recited in claim 1, wherein the operation of heating all the hollow nanospheres so that the hollow nanospheres sublimate, and forming a red light-emitting particle layer, a green light-emitting particle layer, and a blue light-emitting particle layer on the substrate comprises:
heating the substrate to a preset temperature so that each hollow nanosphere comparatively closer to the substrate sublime earlier than each other hollow nanosphere comparatively farther away from the substrate; and
forming the red light-emitting layer, the green light-emitting layer, and the blue light-emitting layer.

9. A method for manufacturing a display panel, comprising:
forming a plurality of hollow nanospheres of different sizes, wherein the plurality of hollow nanospheres are respectively filled with red light-emitting particles, blue light-emitting particles, and green light-emitting particles;
performing screening so that each hollow nanosphere filled with red light-emitting particles is disposed in a respective red sub-pixel area of the substrate, each hollow nanosphere filled with green light-emitting particles is disposed in a respective green sub-pixel area of the substrate, and each hollow nanosphere filled with blue light-emitting particles is disposed in a respective blue sub-pixel area of the substrate;
heating all the hollow nanospheres so that the hollow nanospheres sublimate, and forming a red light-emitting particle layer, a green light-emitting particle layer, and a blue light-emitting particle layer on the substrate;
forming a red light-emitting element, a green light-emitting element, and a blue light-emitting element; and
forming an encapsulation layer and a color filter layer to produce the display panel.

10. The method as recited in claim 9, wherein each of the plurality of hollow nanospheres is formed of an iodine material.

11. The method as recited in claim 9, wherein each of the plurality of the hollow nanospheres has a radial width that is greater than or equal to 50 nm and less than or equal to 500 nm.

12. The method as recited in claim 9, wherein the plurality of hollow nanospheres of different sizes comprise a first nanosphere, a second nanosphere, and a third nanosphere with sequentially increasing radial widths; wherein the first nanosphere has a radial width that lies in the range of 50 nm-100 nm, wherein second nanosphere has a radial width that lies in the range of 100 nm-150 nm, wherein the third nanosphere has a radial width that lies in the range of 150 nm-200 nm; wherein the first nanosphere is filled with red light-emitting particles, wherein the second nanosphere is filled with green light-emitting particles, and wherein the third nanosphere is filled with blue light-emitting particles.

13. The method as recited in claim 9, further comprising the following operations prior to the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate:
forming a bottom electrode on the substrate;
forming an isolation layer on the bottom electrode, defining a plurality of pixel openings in the isolation layer and exposing the bottom electrode from the plurality of pixel openings, wherein the plurality of pixel openings comprise the red sub-pixel area, the green sub-pixel area, and the blue sub-pixel area;
wherein in the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate, the plurality of hollow nanospheres of different sizes are screened in sequence using a composite molecular sieve structure;
wherein the operation of forming the red light-emitting element, the green light-emitting element, and the blue light-emitting element comprises forming a top electrode to form the red light-emitting element, the green light-emitting element, and the blue light-emitting element.

14. The method as recited in claim 13, wherein the composite molecular sieve structure comprises a first molecular sieve membrane disposed corresponding to the red sub-pixel areas, a second molecular sieve membrane disposed corresponding to the blue sub-pixel areas, and a third molecular sieve membrane disposed corresponding to the green sub-pixel areas;
wherein the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate comprises:
using the first molecular sieve membrane to screen out each hollow nanosphere filled with red light-emitting particles, and depositing the hollow nanosphere filled with red light-emitting particles in the respective red sub-pixel area;
using the second molecular sieve membrane to screen out each hollow nanosphere filled with green light-emitting particles, and depositing the hollow nanosphere filled with green light-emitting particles in the respective green sub-pixel area; and
using the third molecular sieve membrane to screen out each hollow nanosphere filled with blue light-emitting particles, and depositing the hollow nanosphere filled with blue light-emitting particles in the respective blue sub-pixel area.

15. The method as recited in claim 14, wherein the composite molecular sieve structure further comprises a first cover plate, a second cover plate and a third cover plate, wherein the first cover plate is arranged corresponding to the first molecular sieve membrane, wherein the second cover plate is arranged corresponding to the second molecular sieve membrane, and wherein the third cover plate is arranged corresponding to the third molecular sieve membrane; wherein the operation of performing screening so that each hollow nanosphere filled with red light-emitting particles is disposed in the respective red sub-pixel area of the substrate, each hollow nanosphere filled with green light-emitting particles is disposed in the respective green sub-pixel area of the substrate, and each hollow nanosphere filled with blue light-emitting particles is disposed in the respective blue sub-pixel area of the substrate comprises:
opening the first cover plate and closing the second cover plate and the third cover plate, and screening out each hollow nanosphere filled with red light-emitting particles through the first molecular sieve membrane, and depositing each hollow nanosphere filled with red light-emitting particles in the respective red sub-pixel area;
opening the second cover plate and closing the first cover plate and the third cover plate, and screening out each hollow nanosphere filled with green light-emitting particles through the second molecular sieve membrane, and depositing each hollow nanosphere filled with green light-emitting particles in the respective red sub-pixel area;
opening the third cover plate and closing the first cover plate and the second cover plate, and screening out each hollow nanosphere filled with blue light-emitting particles through the third molecular sieve membrane, and depositing each hollow nanosphere filled with blue light-emitting particles in the respective blue sub-pixel area.

16. The method as recited in claim 9, wherein the operation of heating all the hollow nanospheres so that the hollow nanospheres sublimate, and forming a red light-emitting particle layer, a green light-emitting particle layer, and a blue light-emitting particle layer on the substrate comprises:
heating the substrate to a preset temperature so that each hollow nanosphere comparatively closer to the substrate sublime earlier than each other hollow nanosphere comparatively farther away from the substrate; and
forming the red light-emitting layer, the green light-emitting layer, and the blue light-emitting layer.

17. A display panel, comprising a plurality of light-emitting elements, wherein the light-emitting elements are formed by a method for manufacturing a light-emitting element, the method comprising:
forming a plurality of hollow nanospheres of different sizes, wherein the plurality of hollow nanospheres are respectively filled with red light-emitting particles, blue light-emitting particles, and green light-emitting particles;
performing screening so that each hollow nanosphere filled with red light-emitting particles is disposed in a respective red sub-pixel area of the substrate, each hollow nanosphere filled with green light-emitting particles is disposed in a respective green sub-pixel area of the substrate, and each hollow nanosphere filled with blue light-emitting particles is disposed in a respective blue sub-pixel area of the substrate;
heating all the hollow nanospheres so that the hollow nanospheres sublimate, and forming a red light-emitting particle layer, a green light-emitting particle layer, and a blue light-emitting particle layer on the substrate;
forming a red light-emitting element, a green light-emitting element, and a blue light-emitting element; and
forming an encapsulation layer and a color filter layer to produce the display panel.
